(19) United States
(12) Patent Application Publication
(10) Pub. No.: US 2002/0157819 A1
(43) Pub. Date: Oct. 31, 2002

(54) Graphite-based thermal dissipation component

(76) Inventors: Julian Norley, Chagrin Falls, OH (US); George Getz, Parma Heights, OH (US)

Correspondence Address: JAMES R CARTIGLIA, GRAFTECH INC., 1521 CONCORD PIKE SUITE 301, WILIMINGTON, DE, 19803, US

(21) Appl. No.: 09/888,972

(22) Filed: Jun. 25, 2001

Related U.S. Application Data
(63) Continuation-in-part of application No. 09/826,225, filed on Apr. 4, 2001.

(51) Int. Cl. F28F 7/00; H05K 7/20

(52) U.S. Cl. 165/185; 165/905; 361/704

(57) ABSTRACT

A process is presented for forming an anisotropic heat spreader or heat pipe, comprising forming a laminate comprising a plurality of flexible graphite sheets which comprise graphene layers; and directionally aligning the graphene layers of the laminate.

### TECHNICAL FIELD

The present invention relates to a graphite-based heat spreader or heat pipe that can function to channel heat from a heat source such as an electronic component to facilitate dissipation of the heat. More particularly, the present invention relates to a thermal management system effective for dissipating the heat generated by an electronic component, and which includes a graphite-based heat spreader or heat pipe.

### BACKGROUND OF THE INVENTION

With the development of increasingly sophisticated electronic components, including those capable of greater processing speeds and higher frequencies, having smaller size and more complicated power requirements, and exhibiting other technological advances, relatively extreme temperatures can be generated. Such components include microprocessors and integrated circuits in electronic and electrical components and systems as well as in other devices such as communications equipment and high power optical devices. However, microprocessors, integrated circuits and other sophisticated electronic components typically operate efficiently only under a certain range of threshold temperatures. The excessive heat generated during operation of these components can not only harm their own performance, but can also degrade the performance and reliability of the overall system and can even cause system failure. The increasingly wide range of environmental conditions, including temperature extremes, in which electronic systems are expected to operate, exacerbates these negative effects.

With the increased need for heat dissipation from microelectronic devices caused by these conditions, thermal management becomes an increasingly important element of the design of electronic products. As noted, both performance reliability and life expectancy of electronic equipment are often inversely related to the component temperature of the equipment.

For instance, a reduction in the operating temperature of a device such as a typical silicon semiconductor can correspond to an exponential increase in the reliability and life expectancy of the device. Therefore, to maximize the life-span and reliability of a component, controlling the device operating temperature within the limits set by the designers can be of paramount importance.

Thermal interfaces, heat sinks, heat pipes and heat spreaders are components that facilitate heat dissipation from the surface of a heat source, such as a heat-generating electronic component, to a cooler environment, usually air. In many typical situations, heat transfer between the solid surface of the component and the air is the least efficient within the system, and the solid-air interface thus represents the greatest barrier for heat dissipation. A heat sink seeks to increase the heat transfer efficiency between the components and the ambient air primarily by increasing the surface area that is in direct contact with the air. This allows more heat to be dissipated and thus lowers the device operating temperature. The primary purpose of a heat sink is to help maintain the device temperature below the maximum allowable temperature specified by its designer/manufacturer.

A thermal interface serves to facilitate the transfer of heat from the heat source to another component such as a heat sink or a heat spreader. For instance, conventional heat sinks are generally formed of a metal such as copper and thus have surface irregularities and deformations common to metals, and it is likely that the surface of the electronic component to which a copper heat sink is being joined is also metal or another relatively rigid material such as aluminum oxide or a ceramic material, making a complete connection between a copper heat sink and the component, so as to maximize heat transfer from the component to the copper heat sink, can be difficult without a relatively high pressure mount (often well in excess of 50 pounds per square inch (psi)), which is undesirable since damage to the electronic component could result. When a thermal interface is used, its conformability to the surface topography of the external surface of the electronic component as well as to a metallic heat sink can help form a good thermal connection between the electronic component and a heat sink having surface deformations without application of potentially damaging pressure. Pressures less than 50 psi are usually all that are needed; in fact pressures as low as 15 psi and even lower are often sufficient to create an effective thermal connection between the electronic component, the thermal interface and a heat sink. The use of a flexible graphite sheet for a thermal interface has been suggested in the art.

Heat spreaders and heat pipes act to conduct heat away from the heat source to another location where the heat can be more conveniently removed. Heat spreaders also help in improving the diffusion of heat from a relatively small area heat source to a larger surface area. For instance, a heat spreader can be used in conjunction with a heat pipe or another component to move the heat from an electronic component such as a chipset assembly to a fan or fan/heat sink arrangement. Conventionally, heat spreaders and heat pipes are formed of a metal.

Limitations exist, however, with the use of metallic heat sinks, heat spreaders and heat pipes. One limitation relates to a metal's relative isotropy—that is, the tendency of a metallic structure to distribute heat relatively evenly about the structure. The isotropy of a metal like copper means that heat transmitted to the heat sink become distributed about the structure rather than being directed to the fins where most efficient transfer to the air occurs. This can reduce the efficiency of heat dissipation using a metallic heat sink. In addition, the use of thermal management components made of copper or aluminum can present a problem because of the weight of the metal, particularly when the surface area of the component from which heat is desired to be dissipated is significantly smaller than that of the heat sink. For instance, pure copper has a density of 8.96 grams per cubic centimeter (g/cc) and has a measured thermal conductivity of 400 watts per meter-° C. (W/m° C.), and pure aluminum has a density of 2.7 g/cc and has a measured thermal conductivity of 237 W/m° C. (the grade of aluminum generally used commercially in heat sink applications, alloy 6061, has a density of 2.7 g/cc and a thermal conductivity of 180 W/m° C.).

What is desired, therefore, is a thermal dissipation component such as a heat spreader or heat pipe effective for transferring heat from a heat source such as an electronic component to a location where dissipation can occur. The dissipation component should advantageously be relatively anisotropic as compared to copper, have thermal conductivity in the desired direction comparable to a metal, and exhibit a relatively high ratio of thermal conductivity to weight.

Graphites are made up of layer planes of hexagonal arrays or networks of carbon atoms. These layer planes of hexagonally arranged carbon atoms are substantially flat and are oriented or ordered so as to be substantially parallel and equidistant to one another. The substantially flat, parallel equidistant sheets or layers of carbon atoms, usually referred to as graphene layers or basal planes, are linked or bonded together and groups thereof are arranged in crystallites. Highly ordered graphites consist of crystallites of considerable size: the crystallites being highly aligned or oriented with respect to each other and having well ordered carbon layers. In other words, highly ordered graphites have a high degree of preferred crystallite orientation. It should be noted that graphites possess anisotropic structures and thus exhibit or possess many properties that are highly directional e.g. thermal and electrical conductivity and fluid diffusion.

Briefly, graphites may be characterized as laminated structures of carbon, that is, structures consisting of superposed layers or laminae of carbon atoms joined together by weak van der Waals forces. In considering the graphite structure, two axes or directions are usually noted, to wit, the “c” axis or direction and the “a” axes or directions. For simplicity, the “c” axis or direction may be considered as the direction perpendicular to the carbon layers. The “a” axes or directions may be considered as the directions parallel to the carbon layers or the directions perpendicular to the “c” direction. The graphites suitable for manufacturing flexible graphite sheets possess a very high degree of orientation.

As noted above, the bonding forces holding the parallel layers of carbon atoms together are only weak van der Waals forces. Natural graphites can be treated so that the spacing between the superposed carbon layers or laminae can be appreciably opened up so as to provide a marked expansion in the direction perpendicular to the layers, that is, in the “c” direction, and thus form an expanded or intumesced graphite structure in which the laminar character of the carbon layers is substantially retained.

Graphite flake which has been greatly expanded and more particularly expanded so as to have a final thickness or “c” direction dimension which is as much as about 80 or more times the original “c” direction dimension can be formed without the use of a binder into cohesive or integrated sheets of expanded graphite, e.g. webs, papers, strips, tapes, or the like (typically referred to as “flexible graphite”). The formation of graphite particles which have been expanded to have a final thickness or “c” dimension which is as much as about 80 times or more the original “c” direction dimension into integrated flexible sheets by compression, without the use of any binding material, is believed to be possible due to the mechanical interlocking, or cohesion, which is achieved between the voluminously expanded graphite particles.

In addition to flexibility, the sheet material, as noted above, has also been found to possess a high degree of anisotropy with respect to thermal and electrical conductivity and fluid diffusion, comparable to the natural graphite starting material due to orientation of the expanded graphite particles substantially parallel to the opposed faces of the sheet resulting from very high compression, e.g. roll pressing. Sheet material thus produced has excellent flexibility, good strength and a very high degree of orientation.

Briefly, the process of producing flexible, binderless anisotropic graphite sheet material, e.g. web, paper, strip, tape, foil, mat, or the like, comprises compressing or compacting under a predetermined load and in the absence of a binder, expanded graphite particles which have a “c” direction dimension which is as much as about 80 or more times that of the original particles so as to form a substantially flat, flexible, integrated graphite sheet. The expanded graphite particles that generally are worm-like or vermiform in appearance, once compressed, will maintain the compression set and alignment with the opposed major surfaces of the sheet. The density and thickness of the sheet material can be varied by controlling the degree of compression. The density of the sheet material can be within the range of from about 0.04 g/cc to about 2.0 g/cc. The flexible graphite sheet material exhibits an appreciable degree of anisotropy due to the alignment of graphite particles parallel to the major opposed, parallel surfaces of the sheet, with the degree of anisotropy increasing upon roll pressing of the sheet material to increased density. In roll pressed anisotropic sheet material, the thickness, i.e. the direction perpendicular to the opposed, parallel sheet surfaces comprises the “c” direction and the directions ranging along the length and width, i.e. along or parallel to the opposed, major surfaces comprises the “a” directions and the thermal, electrical and fluid diffusion properties of the sheet are very different, by orders of magnitude, for the “c” and “a” directions.

### SUMMARY OF THE INVENTION

It is an object of the present invention to provide a thermal dissipation component such as a heat spreader or a heat pipe to be used in conjunction with a heat source, the dissipation component being effective to transfer heat from the heat source, such as an electronic component to facilitate dissipation.

Another object of the present invention is to provide a heat spreader or a heat pipe exhibiting a relatively high degree of thermal anisotropic ratio.

Still another object of the present invention is to provide a heat spreader solution having thermal conductivity at least comparable to metallic heat spreaders.

Yet another object of the present invention is to provide a heat spreader having a relatively high ratio of thermal conductivity to weight.

Another object of the present invention is to provide a heat pipe solution having thermal conductivity at least comparable to metallic heat pipes.

Still another object of the present invention is to provide a heat pipe having a relatively high ratio of thermal conductivity to weight.

### DETAILED DESCRIPTION OF THE INVENTION

Graphite is a crystalline form of carbon comprising atoms covalently bonded in flat layered planes with weaker bonds between the planes. By treating particles of graphite, such as natural graphite flake, with an intercalant of, e.g. a solution of sulfuric and nitric acid, the crystal structure of the graphite reacts to form a compound of graphite and the intercalant. The treated particles of graphite are hereafter referred to as “particles of intercalated graphite.” Upon exposure to high temperature, the intercalant within the graphite decomposes and volatilizes, causing the particles of intercalated graphite to expand in dimension as much as about 80 or more times its original volume in an accordion-like fashion in the “c” direction, i.e. in the direction perpendicular to the crystalline planes of the graphite. The exfoliated graphite particles are vermiform in appearance, and are therefore commonly referred to as worms. The worms may be compressed together into flexible sheets that, unlike the original graphite flakes, can be formed and cut into various shapes and provided with small transverse openings by deforming mechanical impact.

Graphite starting materials suitable for use in the present invention include highly graphitic carbonaceous materials capable of intercalating organic and inorganic acids as well as halogens and then expanding when exposed to heat. These highly graphitic carbonaceous materials most preferably have a degree of graphitization of about 1.0. As used in this disclosure, the term “degree of graphitization” refers to the value g according to the formula:

$$g = \frac{3.45 - d ( 002 )}{0.095}$$

where d(002) is the spacing between the graphitic layers of the carbons in the crystal structure measured in Angstrom units. The spacing d between graphite layers is measured by standard X-ray diffraction techniques. The positions of diffraction peaks corresponding to the (002), (004) and (006) Miller Indices are measured, and standard least-squares techniques are employed to derive spacing which minimizes the total error for all of these peaks. Examples of highly graphitic carbonaceous materials include natural graphites from various sources, as well as other carbonaceous materials such as carbons prepared by chemical vapor deposition and the like. Natural graphite is most preferred.

The graphite starting materials used in the present invention may contain non-carbon components so long as the crystal structure of the starting materials maintains the required degree of graphitization and they are capable of exfoliation. Generally, any carbon-containing material, the crystal structure of which possesses the required degree of graphitization and which can be exfoliated, is suitable for use with the present invention. Such graphite preferably has an ash content of less than about twenty weight percent. More preferably, the graphite employed for the present invention will have a purity of at least about 94%. In the most preferred embodiment, the graphite employed will have a purity of at least about 98%.

A common method for manufacturing graphite sheet is described by Shane et al in U.S. Pat. No. 3,404,061, the disclosure of which is incorporated herein by reference. In the typical practice of the Shane et al. method, natural graphite flakes are intercalated by dispersing the flakes in a solution containing e.g., a mixture of nitric and sulfuric acid, advantageously at a level of about 20 to about 300 parts by weight of intercalant solution per 100 parts by weight of graphite flakes (pph). The intercalation solution contains oxidizing and other intercalating agents known in the art. Examples include those containing oxidizing agents and oxidizing mixtures, such as solutions containing nitric acid, potassium chlorate, chromic acid, potassium permanganate, potassium chromate, potassium dichromate, perchloric acid, and the like, or mixtures, such as for example, concentrated nitric acid and chlorate, chromic acid and phosphoric acid, sulfuric acid and nitric acid, or mixtures of a strong organic acid, e.g. trifluoroacetic acid, and a strong oxidizing agent soluble in the organic acid. Alternatively, an electric potential can be used to bring about oxidation of the graphite. Chemical species that can be introduced into the graphite crystal using electrolytic oxidation include sulfuric acid as well as other acids.

In a preferred embodiment, the intercalating agent is a solution of a mixture of sulfuric acid, or sulfuric acid and phosphoric acid, and an oxidizing agent, i.e. nitric acid, perchloric acid, chromic acid, potassium permanganate, hydrogen peroxide, iodic or periodic acids, or the like. Although less preferred, the intercalation solution may contain metal halides such as ferric chloride, and ferric chloride mixed with sulfuric acid, or a halide, such as bromine as a solution of bromine and sulfuric acid or bromine in an organic solvent.

The quantity of intercalation solution may range from about 20 to about 150 pph and more typically about 50 to about 120 pph. After the flakes are intercalated, any excess solution is drained from the flakes and the flakes are water-washed. Alternatively, the quantity of the intercalation solution may be limited to between about 10 and about 50 pph, which permits the washing step to be eliminated as taught and described in U.S. Pat. No. 4,895,713, the disclosure of which is also herein incorporated by reference.

The particles of graphite flake treated with intercalation solution can optionally be contacted, e.g. by blending, with a reducing organic agent selected from alcohols, sugars, aldehydes and esters which are reactive with the surface film of oxidizing intercalating solution at temperatures in the range of 25° C. and 125° C. Suitable specific organic agents include hexadecanol, octadecanol, 1-octanol, 2-octanol, decylalcohol, 1, 10 decanediol, decylaldehyde, 1-propanol, 1,3 propanediol, ethyleneglycol, polypropylene glycol, dextrose, fructose, lactose, sucrose, potato starch, ethylene glycol monostearate, diethylene glycol dibenzoate, propylene glycol monostearate, glycerol monostearate, dimethyl oxylate, diethyl oxylate, methyl formate, ethyl formate, ascorbic acid and lignin-derived compounds, such as sodium lignosulfate. The amount of organic reducing agent is suitably from about 0.5 to 4% by weight of the particles of graphite flake.

The use of an expansion aid applied prior to, during or immediately after intercalation can also provide improvements. Among these improvements can be reduced exfoliation temperature and increased expanded volume (also referred to as “worm volume”). An expansion aid in this context will advantageously be an organic material sufficiently soluble in the intercalation solution to achieve an improvement in expansion. More narrowly, organic materials of this type that contain carbon, hydrogen and oxygen, preferably exclusively, may be employed. Carboxylic acids have been found especially effective. A suitable carboxylic acid useful as the expansion aid can be selected from aromatic, aliphatic or cycloaliphatic, straight chain or branched chain, saturated and unsaturated monocarboxylic acids, dicarboxylic acids and polycarboxylic acids which have at least 1 carbon atom, and preferably up to about 15 carbon atoms, which is soluble in the intercalation solution in amounts effective to provide a measurable improvement of one or more aspects of exfoliation. Suitable organic solvents can be employed to improve solubility of an organic expansion aid in the intercalation solution.

Representative examples of saturated aliphatic carboxylic acids are acids such as those of the formula H(CH₂)ₙCOOH wherein n is a number of from 0 to about 5, including formic, acetic, propionic, butyric, pentanoic, hexanoic, and the like. In place of the carboxylic acids, the anhydrides or reactive carboxylic acid derivatives such as alkyl esters can also be employed. Representative of alkyl esters are methyl formate and ethyl formate. Sulfuric acid, nitric acid and other known aqueous intercalants have the ability to decompose formic acid, ultimately to water and carbon dioxide. Because of this, formic acid and other sensitive expansion aids are advantageously contacted with the graphite flake prior to immersion of the flake in aqueous intercalant. Representative of dicarboxylic acids are aliphatic dicarboxylic acids having 2-12 carbon atoms, in particular oxalic acid, fumaric acid, malonic acid, maleic acid, succinic acid, glutaric acid, adipic acid, 1,5-pentanedicarboxylic acid, 1,6-hexanedicarboxylic acid, 1,10-decanedicarboxylic acid, cyclohexane-1,4-dicarboxylic acid and aromatic dicarboxylic acids such as phthalic acid or terephthalic acid. Representative of alkyl esters are dimethyl oxylate and diethyl oxylate. Representative of cycloaliphatic acids is cyclohexane carboxylic acid and of aromatic carboxylic acids are benzoic acid, naphthoic acid, anthranilic acid, p-aminobenzoic acid, salicylic acid, o-, m- and p-tolyl acids, methoxy and ethoxybenzoic acids, acetoacetamidobenzoic acids and, acetamidobenzoic acids, phenylacetic acid and naphthoic acids. Representative of hydroxy aromatic acids are hydroxybenzoic acid, 3-hydroxy-1-naphthoic acid, 3-hydroxy-2-naphthoic acid, 4-hydroxy-2-naphthoic acid, 5-hydroxy-1-naphthoic acid, 5-hydroxy-2-naphthoic acid, 6-hydroxy-2-naphthoic acid and 7-hydroxy-2-naphthoic acid. Prominent among the polycarboxylic acids is citric acid.

The intercalation solution will be aqueous and will preferably contain an amount of expansion aid of from about 1 to 10%, the amount being effective to enhance exfoliation. In the embodiment wherein the expansion aid is contacted with the graphite flake prior to or after immersing in the aqueous intercalation solution, the expansion aid can be admixed with the graphite by suitable means, such as a V-blender, typically in an amount of from about 0.2% to about 10% by weight of the graphite flake.

After intercalating the graphite flake, and following the blending of the intercalant coated intercalated graphite flake with the organic reducing agent, the blend is exposed to temperatures in the range of 25° to 125° C. to promote reaction of the reducing agent and intercalant coating. The heating period is up to about 20 hours, with shorter heating periods, e.g., at least about 10 minutes, for higher temperatures in the above-noted range. Times of one half hour or less, e.g., on the order of 10 to 25 minutes, can be employed at the higher temperatures.

The thus treated particles of graphite are sometimes referred to as “particles of intercalated graphite.” Upon exposure to high temperature, e.g. temperatures of at least about 160° C. and especially about 700° C. to 1000° C. and higher, the particles of intercalated graphite expand as much as about 80 to 1000 or more times their original volume in an accordion-like fashion in the c-direction, i.e. in the direction perpendicular to the crystalline planes of the constituent graphite particles. The expanded, i.e. exfoliated, graphite particles are vermiform in appearance, and are therefore commonly referred to as worms. The worms may be compressed together into flexible sheets that, unlike the original graphite flakes, can be formed and cut into various shapes.

Flexible graphite sheet and foil are coherent, with good handling strength, and are suitably compressed, e.g. by roll-pressing, to a thickness of about 0.075 mm to 3.75 mm and a typical density of about 0.1 to 1.5 g/cc. From about 1.5-30% by weight of ceramic additives can be blended with the intercalated graphite flakes as described in U.S. Pat. No. 5,902,762 (which is incorporated herein by reference) to provide enhanced resin impregnation in the final flexible graphite product. The additives include ceramic fiber particles having a length of about 0.15 to 1.5 millimeters. The width of the particles is suitably from about 0.04 to 0.004 mm. The ceramic fiber particles are non-reactive and non-adhering to graphite and are stable at temperatures up to about 1100° C., preferably about 1400° C. or higher. Suitable ceramic fiber particles are formed of macerated quartz glass fibers, carbon and graphite fibers, zirconia, boron nitride, silicon carbide and magnesia fibers, naturally occurring mineral fibers such as calcium metasilicate fibers, calcium aluminum silicate fibers, aluminum oxide fibers and the like. Most preferably, however, the flexible graphite sheet does not contain additives such as ceramic fiber particles, in order to optimize thermal conductivity.

The flexible graphite sheet can also, at times, be advantageously treated with resin and the absorbed resin, after curing, enhances the moisture resistance and handling strength, i.e. stiffness, of the flexible graphite sheet (and a laminate formed therefrom, as discussed hereinbelow), as well as “fixing” the morphology of the sheet. Suitable resin content is preferably at least about 5% by weight, more preferably about 10 to 35% by weight, and suitably up to about 60% by weight. Resins found especially useful in the practice of the present invention include acrylic-, epoxy- and phenolic-based resin systems, or mixtures thereof. Suitable epoxy resin systems include those based on diglycidyl ether of bisphenol A (DGEBA) and other multifunctional resin systems; phenolic resins that can be employed include resole and novolak phenolics.

In the practice of the present invention, a plurality of the thusly-prepared flexible graphite sheets are laminated into a unitary article, such as a block or other desirable shape. The anisotropic flexible sheets of compressed particles of exfoliated graphite can be laminated with a suitable adhesive, such as pressure sensitive or thermally activated adhesive, therebetween. The adhesive chosen should balance bonding strength with minimal thickness, and be capable of maintaining adequate bonding at the service temperature of the electronic component for which heat dissipation is sought. Suitable adhesives are known to the skilled artisan, and include phenolic resins.

The inventive laminate should be formed of at least 2 layers (indeed, 2-layer laminates have been found to be useful as heat spreaders), and up to at least about 20 layers or more, depending on the particular requirements (size, strength, thermal conductivity characteristics, etc.) of the final component. The laminate should be at least about 1 mm in thickness, and up to about 20 mm, or even about 30 mm or more, in thickness, again based on the particular requirements of the final component.

Generally speaking, the shape of the laminate can vary, with the most typical shape being a block, by which is meant a structure having in-plane dimensions corresponding to the major surfaces (i.e., in-plane direction) of the individual sheets which make up the laminate, and having a thickness generally corresponding to the combined thickness of the component sheets, such that the through-thickness direction of the laminate corresponds to the through-thickness direction of the component sheets. The laminate can be formed wherein one or more of the component flexible graphite sheets is resin impregnated, to provide dimensional strength to the laminate, to facilitate its use as a heat spreader or heat pipe. Most preferably, each of the component sheets is resin impregnated to provide superior dimensional strength.

Indeed, using resin impregnated component flexible graphite sheets in forming the laminate can eliminate or reduce the need for use of an adhesive between the layers of the laminate. More specifically, if the impregnated resin is not cured before formation of the laminate, the impregnant can act to adhere at least some of the layers of the laminate together once it is cured. In this way, whatever thickness is added to the laminate by the adhesive layer can be reduced or even eliminated.

The “a” direction extending parallel to the planar direction of the crystal structure of the graphite of the anisotropic flexible sheets of compressed particles of exfoliated graphite which form the laminated article (in other words, along the direction of the major surfaces of the sheets) is oriented to direct heat from the electronic component for which heat dissipation is desired, in the desired direction. For instance, the laminate can direct heat from a “daughter” board of a computer system, to a “mother” board, or from the “mother” board itself, and then to a heat dissipation system such as a cold plate, etc., as would be familiar to the skilled artisan. In this way, the anisotropic nature of the graphite sheets directs the heat in the desired direction (i.e., in the “a” direction along the laminate), and is not degraded by the presence of the adhesive (when employed). The laminate generally has a density of about 1.1 to about 1.35 g/cc, and a thermal conductivity in the in-plane (i.e., “a”) direction of about 220 to about 250 W/m° C. and through-plane (i.e., “c”) direction of about 4 to about 5 W/m° C. The typical laminate therefore has a thermal anisotropic ratio, or ratio of in-plane thermal conductivity to through-plane thermal conductivity, of about 44 to about 63.

The values of thermal conductivity in the in-plane and through-plane directions of the laminate can be manipulated by altering the directional alignment of the graphene layers of the flexible graphite sheets used to form the laminate, or by altering the directional alignment of the graphene layers of the laminate itself after it has been formed. In this way, the in-plane thermal conductivity of the laminate is increased to levels as high as 350 W/m° C. or even as high as 400 W/m° C. or higher. Indeed, thermal conductivities of about 450 W/m° C. or higher can be obtained. Thus the thermal anisotropic ratio of the laminate is at least about 70, and preferably at least about 90, even if no decrease in the through-plane thermal conductivity of the laminate is observed.

One of the ways this directional alignment of the graphene layers can be achieved is by the application of pressure to the component flexible graphite sheets, either by calendering the sheets (i.e., through the application of shear force) or by die pressing or reciprocal platen pressing (i.e., through the application of compaction), with calendering more effective at producing directional alignment. For instance, as an illustration, a flexible graphite sheet having a density of 1.1 g/cc can be found to have an in-plane thermal conductivity of about 240 W/m° C. and a through-plane conductivity of about 23 W/m° C. (and, thus, a thermal anisotropic ratio of about 10.4). Calendering the sheet to a density of 1.7 g/cc, as opposed to 1.1 g/cc, the in-plane thermal conductivity can be found to have been increased to about 450 W/m° C., and the through-plane thermal conductivity decreased to about 2 W/m° C., thus increasing the thermal anisotropic ratio of the individual sheets to about 225. A laminate formed from the “densified” sheets would then have a higher thermal anisotropic ratio than one formed from the “undensified” sheets.

Alternatively, once the laminate is formed, the directional alignment of the graphene layers which make up the laminate in gross is increased, such as by the application of pressure, resulting in a density greater than the starting density of the component flexible graphite sheets that make up the laminate. Indeed, a final density for the laminated article of at least about 1.4 g/cc, more preferably at least about 1.6 g/cc, and up to about 2.0 g/cc can be obtained in this manner. The pressure can be applied by conventional means, such as by die pressing or calendering. Pressures of at least about 60 megapascals (MPa) are preferred, with pressures of at least about 550 MPa, and more preferably at least about 700 MPa, needed to achieve densities as high as 2.0 g/cc. Again, in-plane thermal conductivity of at least about 350 W/m° C., and as high as about 450 W/m° C. or even higher, can be obtained in this manner.

Surprisingly, increasing the directional alignment of the graphene layers can increase the in-plane thermal conductivity of the graphite laminate to conductivities which are equal to or even greater than that of pure copper, while the density remains a fraction of that of pure copper. Moreover, the thermal anisotropic ratio of the resulting “aligned” laminates are substantially higher than the “pre-aligned” laminates, ranging from at least about 70 to up to about 90 and higher. Additionally, the resulting aligned laminate also exhibits increased strength, as compared to a non-“aligned” laminate. Moreover, the thickness of the resulting laminate is reduced (for instance, to 15 mm or less), which is advantageous, especially where space is at a premium, such as in a laptop computer or hand-held device.

Depending on the intended end-use of the aligned article, the alignment process can create differing degrees of alignment within the laminate, providing further control, and permitting the manipulation, of the anisotropy of the article.

The resulting aligned laminate can then be pressed or formed into a desired shape (indeed, the alignment process can form the laminate into a desired shape), or machined. The shaped, aligned laminate can be used as a thermal solution, such as a heat spreader or heat pipe, and directionally dissipate heat from a heat source, such as an electrical component, potentially at least as well as copper without copper's weight disadvantages. In addition, the laminate can also function to reduce electromagnetic interference (“EMI”) and/or radio frequency interference (“RFI”) in the device in which it is incorporated, leading to further advantages from its use.

The above description is intended to enable the person skilled in the art to practice the invention. It is not intended to detail all of the possible variations and modifications that will become apparent to the skilled worker upon reading the description. It is intended, however, that all such modifications and variations be included within the scope of the invention that is defined by the following claims. The claims are intended to cover the indicated elements and steps in any arrangement or sequence that is effective to meet the objectives intended for the invention, unless the context specifically indicates the contrary.

What is claimed is:

1. A process for producing a heat spreader or heat pipe for an electronic component, comprising forming a laminate comprising a plurality of flexible graphite sheets which comprise graphene layers; and directionally aligning the graphene layers of the laminate.

2. The process of claim 1 wherein directionally aligning the graphene layers of the laminate is effected by the application of pressure.

3. The process of claim 2 wherein the application of pressure is effected after the formation of the laminate from the plurality of flexible graphite sheets.

4. The process of claim 3 wherein the graphene layers of the flexible graphite sheets which make up the laminate are subjected to the application of pressure prior to the formation of the laminate, by increasing the pressure applied to the sheets during the calendering process.

5. The process of claim 2 wherein the application of pressure to the laminate results in an increase in the density of the laminate.

6. The process of claim 4 wherein the increase in the pressure during the calendering process results in the formation of flexible graphite sheets having a greater density.

7. A laminate produced in accordance with the process of claim 1.

8. A laminate produced in accordance with the process of claim 3.

9. A laminate produced in accordance with the process of claim 4.

10. A heat spreader for an electronic component comprising a plurality of flexible graphite sheets laminated into a unitary article, wherein the thermal anisotropic ratio of the article is at least about 70.

11. The heat spreader of claim 10 wherein the thermal anisotropic ratio of the article is at least about 90.

12. The heat spreader of claim 10 wherein the laminate is formed by laminating flexible sheets of compressed particles of exfoliated graphite with a suitable adhesive.

13. The heat spreader of claim 12 wherein the adhesive comprises a pressure sensitive or thermally activated adhesive.

14. A heat pipe for an electronic component comprising a plurality of flexible graphite sheets laminated into a unitary article, wherein the thermal anisotropic ratio of the article is at least about 70.

15. The heat pipe of claim 14 wherein the thermal anisotropic ratio of the article is at least about 90.

16. The heat pipe of claim 14 wherein the laminate is formed by laminating flexible sheets of compressed particles of exfoliated graphite with a suitable adhesive.

17. The heat pipe of claim 16 wherein the adhesive comprises a pressure sensitive or thermally activated adhesive.
